(19) United States
(12) Patent Application Publication
(10) Pub. No.: US 2007/0217163 A1
(43) Pub. Date: Sep. 20, 2007

(54) Implantable medical electronic device with amorphous metallic alloy enclosure

(76) Inventors: Wilson Greatbatch, Williamsville, NY (US); Jeffrey Deal, Clarence, NY (US)

Correspondence Address: WALTER W. DUFT;LAW OFFICES OF WALTER W. DUFT, 8616 MAIN ST, SUITE 2, WILLIAMSVILLE, NY, 14221, US

(21) Appl. No.: 11/376,616

(22) Filed: Mar. 15, 2006

(51) Int. Cl. H05K 7/20

(52) U.S. Cl. 361/719

(57) ABSTRACT

An implantable device includes a device case comprising amorphous non-ferrous metal alloy material and having lower electrical conductivity than crystalline atomic structures comprising the same alloy constituents. The generation of eddy currents is thereby reduced and inductive charging and/or telemetry system operation can take place at higher frequencies with a resulting improvement in energy and data transfer efficiency.

### BACKGROUND OF THE INVENTION

1. Field of the Invention

The present invention relates to improvements in the performance of implantable electronic devices that interface to body tissue for medical diagnostic and/or therapeutic purposes. More specifically, the present invention relates to implantable medical electronic devices that utilize transcutaneous electromagnetic coupling to extracorporeal systems for the transfer of energy and/or information via telemetry.

2. Description of Prior Art

Implantable medical electronic devices have historically found wide application in the treatment of heart disease through the use of pacemakers and implantable cardioverter defibrillators. Within the past decade and continuing to this day, new electrotherapy applications are also being developed for the treatment of neurological disorders. All of these medical electronic devices utilize an internal source of electrical energy to power the device electronics and deliver therapeutic electrical energy. Because the power requirements for many of the neurostimulation applications are significantly higher than those for cardiac stimulation, the neurostimulation device manufacturers are turning to secondary battery systems that can be recharged transcutaneously to provide higher levels of power for much longer periods of time than would be possible with single-use primary battery systems.

Electronic circuits and systems that are to be implanted in living organisms must be hermetically packaged in a way that makes them acceptable to the organism, i.e. biocompatible, and the packaging must protect the electronic circuitry from body fluids in order to guarantee longevity of service. In order to provide a truly hermetic enclosure for the device, the case materials are chosen from a limited set of metals and ceramics. Typically, metals such as stainless steel, titanium or chromium-cobalt alloy are utilized, while suitable ceramic materials include aluminum oxide (Al₂O₃) or zirconium oxide (ZO₂). Unfortunately, both of these classes of materials suffer from serious drawbacks that either limit the performance and durability of the finished devices or contribute significantly to device cost.

Metallic enclosures have been utilized for implantable devices for almost forty years, but the electrically conductive property of the metal presents a limitation to the inductive coupling systems that have been used to implement transcutaneous telemetry and recharging systems. In particular, the formation of eddy currents within the metallic device case due to the impinging alternating current magnetic field severely attenuates the magnetic flux as it passes through the case. With respect to telemetry, the eddy current attenuation limits the rate of information transfer between the implanted device and the external system. This is because the circulating eddy currents absorb energy from the magnetic field and the eddy currents produce a magnetic field that opposes the incident magnetic field. The magnitude of the eddy currents is directly proportional to the frequency of the alternating current magnetic field because the magnitude of the voltage induced within the conductive material is proportional to the time rate of change of magnetic flux as described in Faraday's Law E=-dΦ/dt where E is the induced voltage and Φ is the magnetic flux impinging on the material. The carrier frequency for telemetry is limited by the amount of eddy current attenuation that the system can operate with.

The transfer of transcutaneous energy for recharging implanted device batteries is also a problem because it is necessary to transmit significant amounts of power through the device case in order to recharge the device battery in a reasonable period of time. The induction system constitutes a two-winding transformer with a non-ferrous (air) core where the energy transfer efficiency is directly proportional to the number of turns in the transformer windings and the rate of change (frequency) of the alternating current.
e₂=Mdiᵢ/dt+L₂di₂/dt

In the above expression, e₂ is the voltage induced in the secondary winding, M is the mutual inductance of the primary and secondary windings, L₂ is the inductance of the secondary winding and di₁/dt and di₂/dt are the time rate of change (frequency) of the primary and secondary currents. Because the physical size of the implanted device limits the size, and hence, the inductance (L) of the receiving coil within the device, it is desirable to operate the inductive coupling system at the highest possible frequency in order to obtain the maximum coupling efficiency and energy transfer. Raising the operating frequency increases the eddy current losses however, so that the overall induction system efficiency is severely reduced.

A further problem associated with the generation of eddy currents within the device case material is that the temperature of the device case will increase because the absorbed energy is dissipated as heat. This unwanted side effect imposes additional constraints on the rate of energy transfer to the implanted device.

A number of approaches have been proposed to address the limitations of power transfer by transcutaneous inductive coupling. One approach is to locate the secondary recharging coil externally to the main device enclosure and also fit the coil with a magnetic shield to improve the coupling efficiency. The magnetic shield is formed of a ferrous or paramagnetic material with a higher magnetic permeability than the secondary coil and the surrounding tissue so that the shield serves to concentrate the lines of magnetic flux through the secondary coil (i.e. increasing the coil inductance), which increases the mutual inductance of the system and improves the overall efficiency. The shield is also intended to reduce magnetic flux impinging on the device case with a resulting reduction in eddy currents and the amount of case temperature increase.

This approach has significant shortcomings that limit its utility. First and foremost, it is highly undesirable to introduce any ferromagnetic or paramagnetic materials into the human body, especially in individuals requiring significant medical treatment and follow-up. The primary diagnostic imaging system of choice for many patients is magnetic resonance imaging (MRI) which requires the patient to be exposed to both static and transient magnetic fields on the order of 0.5 to 2.0 Tesla. The presence of a minor amount (>5 grams) of ferromagnetic material may present a safety hazard to the patient due to the mechanical forces induced on the material by the strong magnetic field. Furthermore, even if the mass of the material is small enough to preclude a safety hazard, the presence of small amounts of ferromagnetic or paramagnetic materials in the body will distort the uniform magnetic field of the MRI system, resulting in image artifacts in the vicinity of the offending material that will render the image useless. A secondary shortcoming of this approach is the added device complexity due to the need for components located outside of the hermetic device enclosure and the need for additional hermetic electrical feed-through connections between the secondary coil and internal electronic circuitry.

A second approach that has been taken to address the limitations of inductive coupling systems due to eddy current losses is the use of ceramic materials for the entire device enclosure. The secondary coil resides within the hermetic device enclosure. Although this design approach eliminates the possibility of eddy current losses in the device case, it suffers from serious shortcomings. For example, the cost to fabricate a ceramic enclosure is much higher than that of a metal case because of materials and the labor involved. The ceramic enclosure is also quite brittle and subject to fracture from mechanical shock before and after implantation.

It is to improvements in transcutaneously rechargeable implantable electronic devices for medical use that the present invention is directed. In particular, what is needed is an improved device enclosure that minimizes eddy currents and MRI image artifacts without the attendant disadvantages of the prior art approaches described above.

### SUMMARY OF THE INVENTION

The foregoing problems are solved and an advance in the art is provided by an implantable medical electronic device that includes a device enclosure comprising amorphous non-ferrous metal alloy material and having lower electrical conductivity than crystalline atomic structures, whereby the generation of eddy currents is reduced and inductive charging and/or telemetry system operation can take place at higher frequencies with a resulting improvement in energy and data transfer efficiency. MRI imaging compatibility with a reduction in image artifacts is also provided by the amorphous non-ferrous metal alloy material in the device case enclosure.

### BRIEF DESCRIPTION OF THE DRAWINGS

The foregoing and other features and advantages of the invention will be apparent from the following more particular description of preferred embodiments of the invention, as illustrated in the accompanying Drawings in which:

FIG. 1 is a side elevation view of an implantable medical electronic device constructed in accordance with the present invention as a therapy delivery system, with a portion of the device enclosure broken away to illustrate internal components;

FIG. 2 is an exploded perspective view of the implantable medical electronic device of FIG. 1; and

FIG. 3 is a plan view of another implantable medical electronic device constructed in accordance with the present invention as a battery for a therapy delivery system; and

FIG. 4 is a side view of the implantable medical electronic device of FIG. 3; and

FIG. 5 is a schematic diagram of a test fixture for evaluating eddy current losses in various materials;

FIG. 6 is a photograph of a phantom text fixture to which are affixed samples of various materials to be evaluated by magnetic resonance imaging (MRI); and

FIG. 7 is a photograph of a second phantom test fixture to which are affixed samples of additional materials to be evaluated by MRI;

FIG. 8 is the image resulting from an MRI scan of a conventional medical grade titanium sample affixed to the phantom test fixture of FIG. 6;

FIG. 9 is the image resulting from an MRI scan of an amorphous titanium alloy sample affixed to the phantom test fixture of FIG. 7; and

FIG. 10 is a photograph of the medical grade titanium case attached to the phantom test fixture of FIG. 6 and the underside of the amorphous titanium alloy sample attached to the phantom test fixture of FIG. 7.

### DETAILED DESCRIPTION OF EXEMPLARY EMBODIMENTS

Introduction

Exemplary implantable medical electronic devices having metallic device enclosures constructed in accordance with the invention will now be described. Implantable medical electronic devices that may benefit from the device cases of the invention include, but are not limited to, cardiac pacemakers, implantable defibrillators (ICDs), neurostimulators and other battery powered implantable medical devices, together with the battery units contained therein (which have their own device enclosures). As indicated by way of summary above, the implantable device enclosures disclosed herein are characterized by the use of amorphous non-ferrous metal alloys that reduce eddy currents generated by impinging magnetic fields, and therefore allow inductive charging and/or telemetry system operation to proceed at higher frequencies with a resulting improvement in energy and data transfer efficiency.

### Illustrated Embodiments

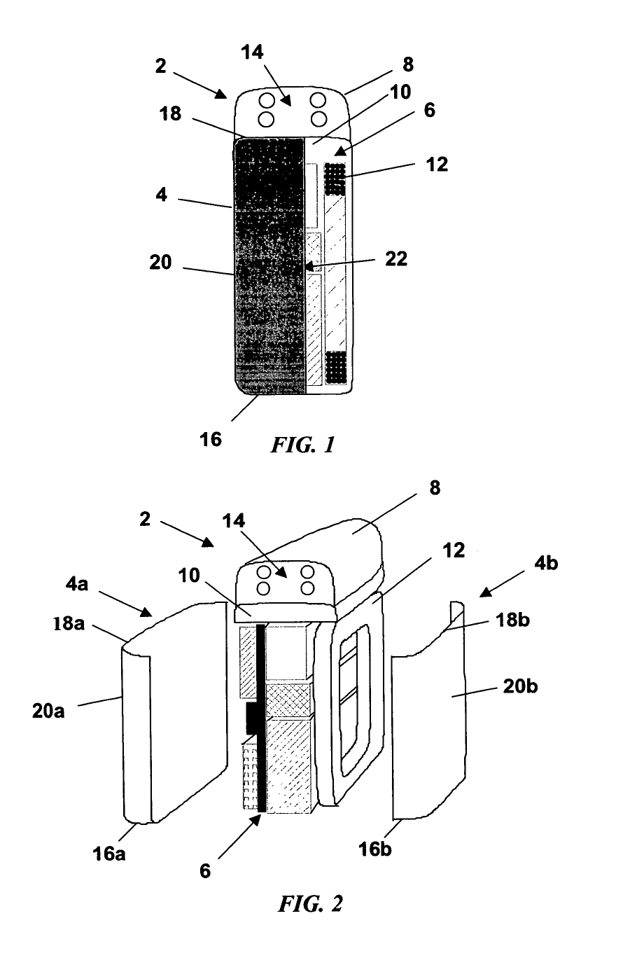

Turning now to the Drawings wherein like reference numerals signify like elements in all of the several views, FIG. 1 illustrates an implantable medical device 2 constructed as a cardiac pacemaker, ICD, neurostimulator or other battery powered therapy delivery system. The device 2 includes device enclosure 4 that is cut away to expose a portion of an internal electronics subassembly 6. The electronics subassembly 6 is attached to a header assembly 8 and hermetically sealed inside the device enclosure 4 by way of a hermetic seal 10. The electronics subassembly 6 functions as a power generating system that includes an internal induction coil 12 or other suitable antenna device, together with a transcutaneous recharging system and/or a telemetry control system. The induction coil 12 provides electromagnetic coupling to an extra-corporeal induction coil (not shown) to support transcutaneous transfer of energy and/or telemetry to the device 2 when it is implanted in a patient. Electrical contacts 14 on the header are connected to the electronics subassembly 6 to deliver an electrical energy output from the device 2.

It will be seen in FIG. 1 that the device enclosure 4 is formed with a closed base end 16, an open end 18 that mounts the header assembly 3, and a major side wall portion 20 that defines an interior cavity 22 for housing the electronics subassembly 2. FIG. 2 represents a perspective view of the device 2 in which the device enclosure 4 is, by way of example only, formed by two enclosure halves 4a and 4b situated on either side of the electronics subassembly 6. The enclosure halves 4a and 4b respectively include closed end portions 16a and 16b, open end portions 18a and 18b and major side wall portions 20a and 20b. At final assembly, the enclosure halves 4a and 4b may be joined to the electronics subassembly 6 and to each other by means of conventional welding techniques. The enclosure halves 4a and 4b may also be welded to the header assembly 8, in which case the hermetic seal 10 will be provided by a weld line. Although not shown, the device enclosure 4 could also have a single-piece construction. Alternatively, multiple enclosure members could be used.

To achieve the objects of the invention, the device enclosure 4 is made of an amorphous non-ferrous metal alloy material having lower electrical conductivity than crystalline atomic structures comprising the same alloy constituents. As explained in more detail below, a preferred material is an amorphous metal comprising a titanium alloy. The reduced conductivity of this enclosure material provides a significant reduction in the eddy current losses associated with the transfer of energy through the material via electromagnetic induction. At the same time, improved MRI compatibility, which is important for an implantable device, is also provided. Other amorphous non-ferrous metal alloys could potentially also be used.

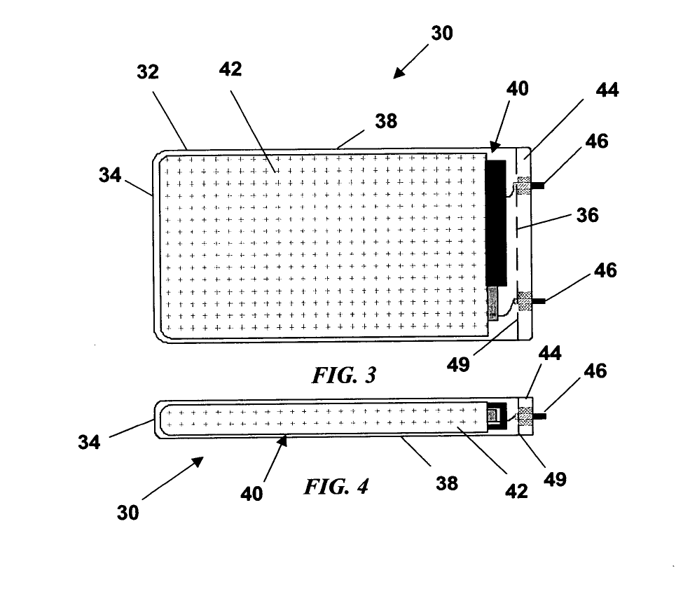

Turning now to FIG. 3, an alternative implantable medical electronic device 30 is constructed as a battery. The battery 30 is enclosed within a device enclosure 32 formed of amorphous non-ferrous alloy material, such as a titanium alloy of the type described in more detail below. The device enclosure 32 is configured with a closed base end 34, an open end 36, and a major side wall portion 38 that defines an interior cavity 40. The battery active materials 42, which provide the battery's energy generating system, have a flat prismatic form factor. The open end 36 of the battery enclosure 32 is fitted with a header assembly 44 in which two glass-to-metal hermetic feed-through terminals 46 are provided for the electrical connections. A hermetic seal 49 can be formed by welding the device enclosure 32 and the header 44, as is presently practiced with conventional case materials. A side elevation view of the battery 30 is provided in FIG. 4 to reveal the narrow edge dimension as compared to the broad face shown in FIG. 3. To construct the device enclosure 32 with this profile, it may be necessary to use two or more enclosure pieces, as described above in connection with FIGS. 1 and 2.

Rationale for Configuration

In order to recharge a secondary battery system within an implanted device, the recharging system must convey energy from an external source (e.g. commercial utility power) through the skin and tissue of a living organism into the implanted device. The energy received within the device is converted to electrical current that is used to recharge the secondary battery. While it is possible to transmit energy through a conducting medium in different forms (heat, light, electromagnetic waves), the requirement to not harm the intervening living tissue at the power levels required has limited the choice to low frequency electromagnetic waves. Inductive coupling systems have been utilized for over thirty years but have suffered from low efficiency because of poor mutual inductance due to the required physical separation between the transmitting and receiving coils and because of attenuation due to the eddy currents generated within the metallic device case.

Energy losses due to eddy currents are a well known phenomenon in the design of power transformers. In order to maximize the energy transfer efficiency of a transformer it is desirable to couple the maximum amount of magnetic flux from the primary winding to the secondary winding. This is achieved by introducing a core material with high magnetic permeability between the windings, typically an alloy of primarily iron and other materials. When the core material is electrically conductive itself, the alternating current magnetic flux within the core will generate circulating currents within the core material that are referred to as eddy currents. Because the eddy currents form a complete loop within a conductive material and hence, a short-circuit path, the energy removed from the magnetic field in formation of the eddy currents will be dissipated as heat. The traditional practice in transformer design to minimize the losses due to eddy currents is to break the core into a large number of thin segments, or laminations, in order to reduce the maximum conductive path length across the core. The laminations are designed to have a non-conductive surface so that eddy currents cannot travel across the lamination boundaries. Additionally, the core ferrous core material is alloyed with a non-conductive element such as silicon in order to reduce its electrical conductivity. By reducing the conductivity, the path resistance for any closed loop eddy current is increased.

Over the past twenty years, another significant improvement in the design of power transformers has been made through the introduction of amorphous ferrous materials in the construction of the core. Whereas the cores for large power distribution transformers have traditionally been fabricated from grain oriented silicon steel, recent advancements in materials processing have led to the development of amorphous ferromagnetic compounds that exhibit lower core (eddy current) losses than the silicon steel. The reduced eddy current losses are a result of the random, disorganized atomic structure of the material that impedes the flow of electrons through the material, lowering the conductivity below that of even the grain oriented silicon steel.

Turning to the field of implantable devices with inductively coupled energy transfer systems, the fundamental requirements for best power transfer are to maximize the coupling between the primary and secondary coils and to minimize the losses caused by impediments to the magnetic field as a result of materials interposed between the primary and secondary coils. The overwhelming cause of these losses is eddy current attenuation due to the metal enclosure of the implantable device. The vast majority of the devices made today utilize titanium or stainless steel with low magnetic susceptibility. Although these materials are non-ferrous and do not “capture” the magnetic flux, they will nevertheless incur eddy currents when immersed in an alternating current magnetic field due to their electrical conductivity. It is therefore highly desirable to utilize non-ferrous materials with low electrical conductivity in order to provide a case that is as transparent as possible to the alternating current magnetic field.

In addition to the development of amorphous ferrous alloys, there has been significant progress in the development of amorphous non-ferrous alloys. Metallic glasses of this type are described in U.S. Pat. No. 5,618,359 of Lin et al. where exemplary at least quaternary alloys comprise titanium plus an early transition metal (ETM) comprising zirconium or hafnium, and copper plus a late transition metal (LTM) comprising cobalt or nickel (referred to hereinafter as “Ti-ETM-Cu-LTM” alloys). The contents of U.S. Pat. No. 5,618,359 are hereby incorporated herein by this reference. As is the case for most amorphous alloys, the rate of cooling from the liquid state to the solid state is controlled because of its effect on the formation of crystals within the material. Rapid cooling of the molten mixture will prevent the organized growth of a crystalline structure and result in an amorphous solid that is at least 50% by volume glassy or amorphous phase material, and typically 100% amorphous phase. An asserted advantage of the alloys disclosed in U.S. Pat. No. 5,618,359 is that the rate of cooling which can be applied while still maintaining the amorphous phase is slow enough (e.g., preferably less than 10³K/s and most preferably from 1-100K/s) to permit the formation of relatively bulky objects. Hence, the disclosed alloys may be referred to as bulk-solidifying amorphous alloys. By way of example, U.S. Pat. No. 5,68,359 discloses that metallic glass objects having a thickness of at least one millimeter in the smallest dimension and at least 50% amorphous phase material are producible at a cooling rate of about 500K/s using a group of Ti-ETM-Cu-LTM alloys wherein the titanium is present in a range of from 5-20 atomic percent, the copper is present in a range of from 8-42 atomic percent, the early transition metal selected from the group consisting of zirconium and hafnium is present in a range of from 30-57 atomic percent, and the late transition metal selected from the group consisting of nickel and cobalt is present in a range of from 4-37 atomic percent, and wherein up to 4 atomic percent of other transition metals and a total of no more than 2 atomic percent of other elements (such as germanium, phosphorous, carbon, nitrogen or oxygen) may also be present. A specific exemplary alloy thus might have the formula
(Zr_{0.8}Ti_{0.2})₅₇CU₂₀(Ni_{0.5}Co_{0.5})₃₀.

Methods of forming these types of amorphous alloys into articles of interest are described in U.S. Pat. No. 5,711,363 of Scruggs et al., where suitably configured die-casting equipment and rapid cooling of the formed material are aspects of the disclosed process, and U.S. Pat. No. 5,797,443 of Lin et al., where oxygen content is controlled to the prevent crystal formation in the finished article. The contents of U.S. Pat. Nos. 5,711,363 and 5,797,443 are hereby incorporated herein by this reference.

We teach here the application of these types of amorphous non-ferrous metals to the fabrication of enclosures and structures for implantable medical devices with the specific benefit of providing articles with lower electrical conductivity than crystalline metal counterparts. The lower conductivity will mitigate the formation of eddy currents in the presence of alternating current magnetic fields and thereby reduce the attenuation of power in inductively coupled energy transfer and telemetry systems. An additional benefit from the application of these types of amorphous non-ferrous metals, or at least those which comprise amorphous titanium (as reported in the test results presented below), to implantable medical devices and enclosures is improved compatibility with MRI imaging because of reduced image artifacts.

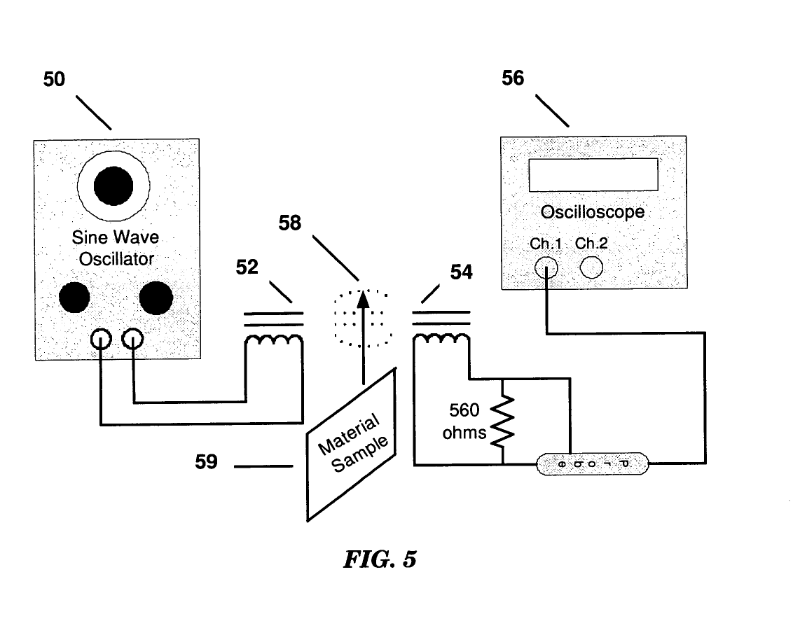

In order to quantify the effect of material conductivity on power transfer in an inductively coupled system, a test apparatus was constructed and a number of material samples were evaluated. Referring to FIG. 5, a sine wave oscillator 50 was used to excite a small transmitting coil 52 that was wound with 36 AWG enamel coated wire on a bobbin, TDK part no. BER 14.5/06-111GA. The bobbin was fitted with one core piece, TDK part no. PC46ER 14.5/6A100 with the open face of the core oriented toward the receiving coil 54. The receiving coil 54 was of identical construction. Both coils had a nominal inductance of 350 microhenries measured at 1 kHz. The coils were affixed to a non-ferrous structure that held them with their core faces aligned at a fixed distance of 3.5 millimeters. The receiving coil 54 was terminated with a 560 ohm resistor and the voltage across the resistor was monitored and measured with an oscilloscope 56. The lines of magnetic flux are depicted in the figure by the dotted lines 58. Each material sample 59 was evaluated by inserting it in the gap between the transmitting coil 52 and the receiving coil 54 and recording the change in the voltage induced in the receiving coil. Measurements were made at three different frequencies and the recorded data is shown in tabular form in Table 1 below. Six different sample materials were evaluated at frequencies of 25 kHz, 100 kHz and 200 kHz. The induced voltage was measured with no sample material present in order to establish a baseline value for the power attenuation calculations shown in the table. The wall thickness of each material sample is provided next to the sample identification.

TABLE 1
Inductive Power Attenuation

| | Test Frequency | | | | | |
|---|---|---|---|---|---|---|
| | 25 kHz | 100 kHz | 200 kHz | 25 kHz | 100 kHz | 200 kHz |
| | Received voltage | | | Received power attenuation | | |
| Material | | | | | | |
| (and minimum | | | | | | |
| thickness dimension) | (mVrms) | (mVrms) | (mVrms) | % Atten. | % Atten. | % Atten. |
| Air | 101 | 301 | 303 | — | — | — |
| Aluminum Foil (.13 | 48.3 | 47 | 26 | 77.1% | 97.6% | 99.3% |
| mm) | | | | | | |
| Nickel Foil (.06 mm) | 73.7 | 144 | 97 | 46.8% | 77.1% | 89.8% |
| 304L SS Foil (.16 | 53 | 63 | 29 | 72.5% | 95.6% | 99.1% |
| mm) | | | | | | |
| SS Can (.3 mm) | 94 | 192 | 138 | 13.4% | 59.3% | 79.3% |
| Ti Can(.52 mm) | 87 | 147 | 91 | 25.8% | 76.1% | 91.0% |
| Amorphous Ti (.66 | 98.6 | 247 | 195 | 4.7% | 32.7% | 58.6% |
| mm) | | | | | | |

The data in Table 1 clearly indicate that the amorphous titanium sample presented the lowest attenuation to the inductive field at all three frequencies, in spite of the fact that it is the thickest of the samples. The significant power attenuation caused by the aluminum foil proves that the inductive field attenuation is not a result of ferromagnetic properties but rather because of eddy currents due to high material conductivity. It is also important to note that the magnitude of attenuation due to eddy currents increases proportionally with frequency as cited earlier herein because of Faraday's Law.

For the purposes of comparison, two of the sample materials tested and shown in Table 1 were taken from actual implantable device enclosures. The “SS Can” sample was an enclosure removed from an implantable cardioverter defibrillator and the “Ti Can” sample was medical grade titanium formed into an implantable device enclosure piece but not completed. The “Amorphous Ti” sample was a portion of an enclosure for a small electronic device. This device was a Cruzer® Titanium USB Flash Drive sold by SanDisk. The device enclosure is fabricated of amorphous titanium material provided by Liquidmetal Technologies pursuant to a license under U.S. Pat. No. 5,618,359 (identified above).

In order to assess relative MRI compatibility, a number of material samples were incorporated onto two testing phantom test fixtures 60 and 64 that were evaluated in a full-body MRI scanner with a static magnetic field strength of 1.5 Tesla. The phantom test fixtures 60 and 64 were comprised of two Plexiglass® sheets, with each sheet separately tested while immersed in two liters of copper sulfate solution with a concentration of 0.2% by weight. The weight of two samples of specific interest is provided in Table 2.

TABLE 2
MRI Test Sample Weights

| Sample | Weight (grams) |
|---|---|
| Titanium Sample (conventional) | 2.88 |
| Amorphous Ti Alloy Sample | 11.64 |

The conventional titanium sample was chosen for this comparison because commercially pure medical grade titanium and titanium alloys have very low magnetic susceptibility when compared to other metals and therefore are well suited for medical implant applications where magnetic resonance imaging is expected to be used. Additional background on MRI compatibility of titanium can be found in Metallic Neurosurgical Implants: Evaluation of Magnetic Field Interactions, Heating, and Artifacts at 1.5 Tesla by Frank G. Shellock, Ph.D. Journal of Magnetic Resonance Imaging, 14:295-299 (2001).

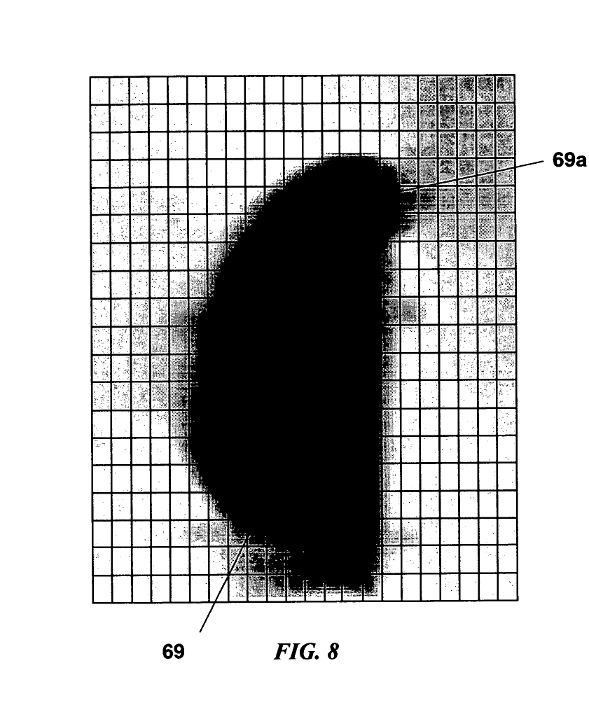

Referring now to FIG. 6, a photograph of the first phantom test fixture 60 is shown. The fixture 60 included six material samples, including the medical grade titanium sample of Table 2 (shown by reference numeral 62). Note that the two left-most samples (66 and 68), each made of 316L stainless steel, had to be removed from the test phantom test fixture 60 after initial scanning because the induced image artifacts from these samples interfered with evaluation of the other samples. The remaining samples 70, 72 and 74 affixed to the phantom test fixture 60 were comprised of 304L stainless steel (sample 70) and silicon carbide (samples 72 and 74). An MRI image 69 for the medical grade titanium sample 62 is provided in FIG. 8. The MRI imaging mode was spin echo with a relaxation time of 717 milliseconds, an echo time of 20 milliseconds, and a bandwidth of 15 kHz. The MRI image 69 has been superimposed on a grid so that the area of the MRI image artifact resulting from the sample may be quantified. Note the shadow artifact 69a appearing at the top of the image 69. The area of the test sample in the image 69 was found to cover approximately 92 squares of the grid and the area of the shadow artifact 69a at the top of the image was found to cover approximately 33 squares of the grid. The artifact area as a percentage of the sample object area was 36%.

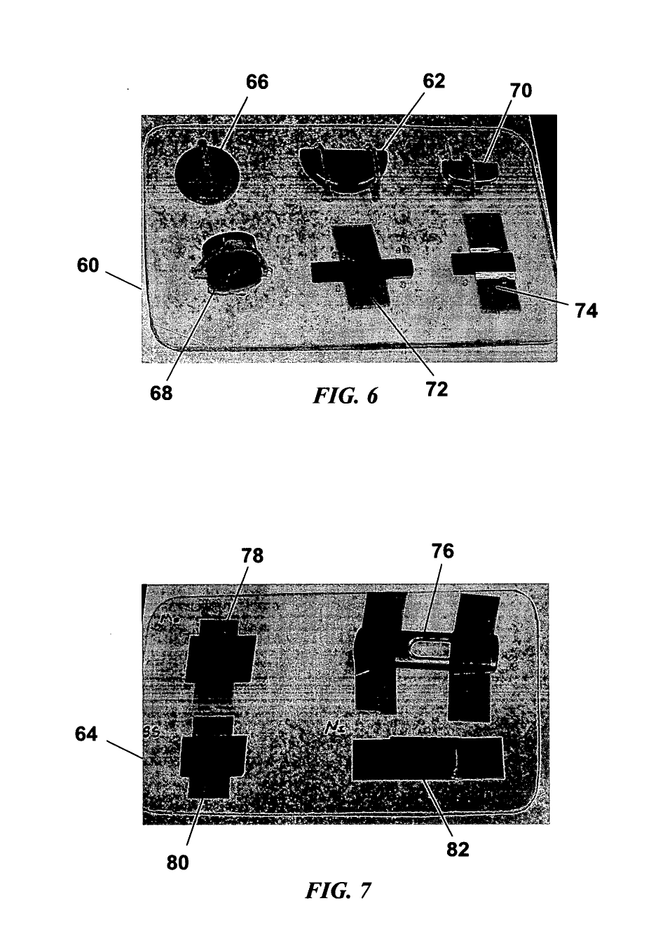

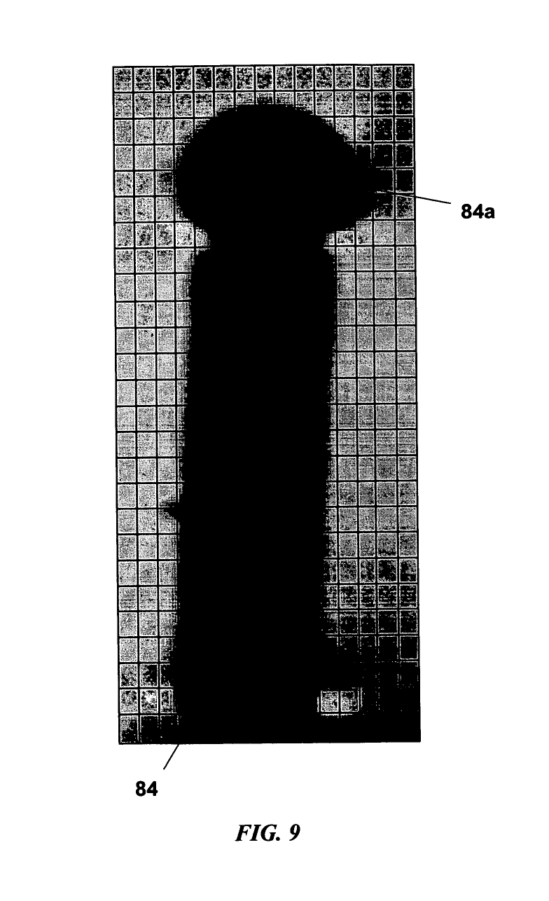

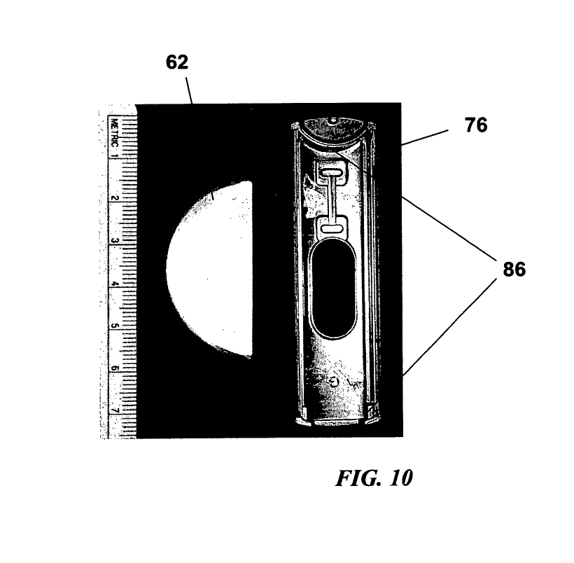

A photograph of the second phantom test fixture 64 is provided in FIG. 7. The items affixed to this phantom test fixture include the above-mentioned amorphous titanium alloy (shown by reference numeral 76) and additional samples 78, 80 and 80. The samples 78, 80 and 82 were comprised of molybdenum foil, stainless steel foil and nickel foil, respectively. An MRI image 84 for the amorphous titanium alloy sample 76 is shown in FIG. 9. The MRI imaging mode was spin echo with a relaxation time of 550 milliseconds, an echo time of 20 milliseconds, and a bandwidth of 15 kHz. The MRI image 84 has been superimposed on a grid so that the area of the MRI image artifact resulting from the amorphous titanium alloy sample 76 may be quantified. The area of the test sample in the image 84 was found to cover approximately 116 squares of the grid and the area of the shadow and “white spot” artifacts on the image was found to cover approximately 42 squares of the grid. The artifact area as a percentage of the sample object area was 36%, the same as for the medical grade titanium sample 62 shown in FIG. 6. The outline of the amorphous titanium alloy sample 76 is clearly visible with artifact “white spots” visible at the four corners and a shadow artifact present at the top of the object image. The cause of these artifacts is attributed to a great extent to the form factor of the underside of the amorphous titanium alloy sample 76, which is shown in the photograph of FIG. 10. Sharp discontinuities 86 in the cross-section thickness of the material at the four corners and the one end of the amorphous titanium alloy sample 76 induce localized distortion in the magnetic field of the MRI which causes the observed artifacts. The medical grade titanium sample 62 is also shown in FIG. 10 for comparison purposes. Although the amorphous titanium alloy sample 76 is larger than the medical grade titanium sample 62, and is four times heavier and significantly more complex in shape, the resulting artifacts were no greater in proportion than those caused by the medical grade titanium sample 62. Thus, it may be rationally concluded that the amorphous titanium alloy material has superior MRI compatibility when compared to conventional medical grade titanium.

Accordingly, the use of amorphous non-ferrous alloys in the fabrication of enclosures for implantable medical devices and device components has been disclosed and the objects of the invention have been achieved. In particular, the composition of the enclosures described above in connection with the various drawing figures provides an improvement in the performance of recharging and telemetry systems for implantable devices by significantly reducing energy losses due to eddy current generation within the device enclosure. The use of amorphous non-ferrous alloys provides the additional benefit of reducing device heating resulting from eddy currents caused by the alternating current magnetic field that is generated by an inductively coupled recharging or telemetry system. It should, of course, be understood that the description and the drawings herein are merely illustrative, and it will be apparent that the various modifications, combinations and changes can be made of these structures disclosed in accordance with the invention. It should be understood, therefore, that the invention is not to be in any way limited except in accordance with the spirit of the appended claims and their equivalents.

What is claimed is:

1. An implantable medical electronic device, comprising:
a device enclosure having a closed first end, a second open end and a major side wall portion defining an interior cavity of said device case;
said enclosure comprising amorphous non-ferrous metal alloy material and having lower electrical conductivity than crystalline atomic structures comprising the same alloy constituents;
an energy generating system in said device case cavity;
a header on said device case;
electrical contacts on said header connected to said energy generating system to deliver an electrical energy output from said device; and
a hermetic seal between said header and said device case.

2. An implantable medical electronic device in accordance with claim 1 wherein said device is a battery powered therapy delivery system.

3. An implantable medical electronic device in accordance with claim 2 wherein said device comprises an internal inductive coil antenna and is adapted for transcutaneous recharging and/or telemetry control.

4. An implantable medical electronic device in accordance with claim 1 wherein said device is a battery.

5. An implantable medical electronic device in accordance with claim 1 wherein said amorphous non-ferrous metal alloy material comprises a titanium alloy that is at least 50% amorphous phase.

6. An implantable medical electronic device in accordance with claim 1 wherein said enclosure is compatible with magnetic resonance imaging.

7. An implantable medical electronic device in accordance with claim 1 wherein said device enclosure comprises two enclosure halves connected together to form said enclosure.

8. An implantable battery powered therapy delivery system, comprising:
a device enclosure having a closed first end, a second open end and a major side wall portion defining an interior cavity of said device case;
said enclosure comprising amorphous non-ferrous metal alloy material and having lower electrical conductivity than crystalline atomic structures comprising the same alloy constituents;
an energy generating system in said device case cavity;
a header on said device case;
electrical contacts on said header connected to said energy generating system to deliver an electrical energy output from said device; and
a hermetic seal between said header and said device case.

9. An implantable battery powered therapy delivery system in accordance with claim 8 wherein said device comprises an internal inductive coil antenna and is adapted for transcutaneous recharging and/or telemetry control.

10. An implantable battery powered therapy delivery system in accordance with claim 8 wherein said amorphous non-ferrous metal alloy material comprises a titanium alloy that is at least 50% amorphous phase.

11. An implantable battery powered therapy delivery system in accordance with claim 8 wherein said enclosure is compatible with magnetic resonance imaging.

12. An implantable battery powered therapy delivery system in accordance with claim 8 wherein said device enclosure comprises two enclosure halves connected together to form said enclosure.

13. An implantable battery, comprising:
a device enclosure having a closed first end, a second open end and a major side wall portion defining an interior cavity of said device case;
said enclosure comprising an amorphous non-ferrous metal alloy material and having lower electrical conductivity than crystalline atomic structures comprising the same alloy constituents;
an energy generating system in said device case cavity;
a header on said device case;
electrical contacts on said header connected to said energy generating system to deliver an electrical energy output from said device; and
a hermetic seal between said header and said device case.

14. An implantable battery in accordance with claim 13 wherein said amorphous non-ferrous metal alloy material comprises a titanium alloy that is at least 50% amorphous phase.

15. An implantable battery in accordance with claim 13 wherein said enclosure is compatible with magnetic resonance imaging.

16. An implantable battery in accordance with claim 13 wherein said device enclosure comprises two enclosure halves connected together to form said enclosure.

17. A method for reducing eddy currents in an implantable medical electronic device enclosure generated by the transcutaneous application of an alternating current magnetic field from an inductive source to an inductive coil antenna within said device enclosure, said method comprising constructing said device enclosure so that it comprises amorphous non-ferrous metal alloy material and has lower electrical conductivity than crystalline atomic structures comprising the same alloy constituents.

18. A method in accordance with claim 18 wherein said amorphous non-ferrous metal alloy material comprises a titanium alloy that is at least 50% amorphous phase.

19. A method in accordance with claim 13 wherein said enclosure is compatible with magnetic resonance imaging.

20. A method for improving the magnetic resonance imaging characteristics of an implantable medical electronic device enclosure comprising constructing said device s enclosure so that it comprises amorphous non-ferrous metal alloy material and has lower electrical conductivity than crystalline atomic structures comprising the same alloy constituents.
